(19) United States
(12) Patent Application Publication
(10) Pub. No.: US 2019/0165250 A1
(43) Pub. Date: May 30, 2019

(54) PIEZOELECTRIC PACKAGE-INTEGRATED PRESSURE SENSING DEVICES

(71) Applicant: Intel Corporation, Santa Clara, CA (US)

(72) Inventors: Thomas L. SOUNART, Chandler, AZ (US); Feras EID, Chandler, AZ (US); Sasha N. OSTER, Chandler, AZ (US); Georgios C. DOGIAMIS, Chandler, AZ (US); Adel A. ELSHERBINI, Chandler, AZ (US); Shawna M. LIFF, Scottsdale, AZ (US); Johanna M. SWAN, Scottsdale, AZ (US)

(21) Appl. No.: 16/097,600

(22) PCT Filed: Jul. 1, 2016
(86) PCT No.: PCT/US2016/040845

§ 371 Date: Oct. 29, 2018

(51) Int. Cl. H01L 41/09; H01L 41/113; B81B 3/00; G01L 9/00

(52) U.S. Cl. CPC H01L 41/0973; H01L 41/1132; B81B 2201/0264; G01L 9/0042; B81B 3/0021

(57) ABSTRACT

Embodiments of the invention include a pressure sensing device having a membrane that is positioned in proximity to a cavity of an organic substrate, a piezoelectric material positioned in proximity to the membrane, and an electrode in contact with the piezoelectric material. The membrane deflects in response to a change in ambient pressure and this deflection causes a voltage to be generated in the piezoelectric material with this voltage being proportional to the change in ambient pressure.

### FIELD OF THE INVENTION

Embodiments of the present invention relate generally to package integrated pressure sensing devices. In particular, embodiments of the present invention relate to piezoelectric package integrated pressure sensing devices (pressure sensors).

### BACKGROUND OF THE INVENTION

Pressure sensors are important for consumer mobile devices to monitor barometric pressure. Pressure sensors also have a wide range of applications in, e.g., industrial equipment and facility monitoring, automotive systems, internet of things (JOT), and mobile health monitoring. Commercially available miniaturized pressure sensors are fabricated on silicon wafer substrates and packaged separately. However, these systems are typically bulky since pressure sensors have a relatively large z-height (>>5 mm). MEMS technology used for the creation of pressure sensors produces much lower z-height than the above systems. However, manufacturing processes for silicon-based MEMS technology are expensive due to expensive materials and wafer-scale fabrication and can be very challenging or possibly not even feasible over large areas.

### BRIEF DESCRIPTION OF THE DRAWINGS

FIG. 1 illustrates a view of a microelectronic device 100 having a package-integrated piezoelectric pressure sensing device, according to an embodiment.

FIG. 2A illustrates a side cross-sectional view of a package substrate 200 having a package-integrated piezoelectric pressure sensing device, according to an embodiment.

FIG. 2B illustrates a side cross-sectional view of a package substrate 250 having a package-integrated piezoelectric pressure sensing device, according to another embodiment.

FIG. 3 illustrates a top view of a package substrate having a package-integrated piezoelectric device (e.g., pressure sensing device), according to another embodiment.

FIG. 4 illustrates a top view of a package substrate having a package-integrated piezoelectric device (e.g., pressure sensing device with square shaped membrane), according to another embodiment.

FIG. 5 illustrates a top view of a package substrate having a package-integrated piezoelectric device (e.g., pressure sensing device with circular shaped membrane), according to another embodiment.

FIG. 6 illustrates a top view of a package substrate having a package-integrated piezoelectric device (e.g., pressure sensing device with interdigitated electrodes), according to another embodiment.

FIG. 7 illustrates a top view of a package substrate having a package-integrated piezoelectric device (e.g., pressure sensing device with first and second electrodes disposed on a same side of a piezoelectric material), according to another embodiment.

FIG. 8 illustrates a cross-sectional view AA of FIG. 6 and also a cross-sectional view BB of FIG. 7 of a package substrate having a package-integrated piezoelectric device (e.g., pressure sensing device with first and second electrodes disposed on a same side of a piezoelectric material), according to another embodiment.

FIG. 9 illustrates a computing device 1500 in accordance with one embodiment of the invention.

### DETAILED DESCRIPTION OF THE INVENTION

Described herein are piezoelectric package integrated pressure sensing devices. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order to not obscure the illustrative implementations.

Various operations will be described as multiple discrete operations, in turn, in a manner that is most helpful in understanding the present invention. However, the order of description should not be construed to imply that these operations are necessarily order dependent. In particular, these operations need not be performed in the order of presentation.

The present design provides thin, low cost pressure sensing devices that are manufactured as part of an organic package substrate traditionally used to route signals between the CPU or other die and the board. The pressure sensing devices (e.g., pressure sensors) are manufactured as part of an electronic package substrate, which reduces z-height and manufacturing costs. These pressure sensors can be made very compact and placed in multiple substrate locations to provide a spatial pressure map of the substrate, which would be useful, for example, if convective cooling is used for package thermal management, such as by an integrated micropump for cooling electronic components. The pressure sensors can also be used for indoor navigation with a mobile device. For example, a pressure level determined by the pressure sensors can be correlated with a particular floor of a building.

The present design results in package-integrated piezoelectric pressure sensing devices, thus enabling thinner systems, tighter integration and more compact form factor in comparison to systems with discrete pressure sensors. The smallest pressure sensors currently available are MEMS devices fabricated on silicon wafer substrates and packaged separately for attachment to an electronic board or other location. In accordance with the present design, which fabricates a pressure sensor in the package substrate directly, the z-height is significantly reduced since the added height from assembling a discrete pressure sensor component is eliminated. This enables thinner platforms. Also, the cost of fabrication is reduced compared to silicon MEMS devices by using lower cost package substrate materials and larger-scale panel-level processing.

Package substrate technology using organic panel-level (e.g., ˜0.5 m×0.5 m sized panels) high volume manufacturing (HVM) processes has significant cost advantages compared to silicon-based MEMS processes since it allows the batch fabrication of more devices using less expensive materials. However, the deposition of high quality piezoelectric thin films has been traditionally limited to inorganic substrates such as silicon and other ceramics due to their ability to withstand the high temperatures required for crystallizing those films. The present design is enabled by a new process to allow the deposition and crystallization of high quality piezoelectric thin films without degrading the organic substrate.

In one example, the present design includes package-integrated structures to act as pressure sensing devices. Those structures are manufactured as part of the package layers and are made free to vibrate or move by removing the dielectric material around them. The structures include piezoelectric stacks that are deposited and patterned layer-by-layer into the package. The present design includes creating pressure sensing devices in the package on the principle of suspended and vibrating structures. Etching of the dielectric material in the package occurs to create cavities. Piezoelectric material deposition (e.g., 0.5 to 1 um deposition thickness) and crystallization also occur in the package substrate during the package fabrication process. An annealing operation at a substrate temperature range (e.g., up to 260° C.) that is lower than typically used for piezoelectric material annealing allows crystallization of the piezoelectric material (e.g., lead zirconate titanate (PZT), potassium sodium niobate (KNN), aluminum nitride (AlN), zinc oxide (ZnO), etc) to occur during the package fabrication process without imparting thermal degradation or damage to the substrate layers. In one example, laser pulsed annealing occurs locally with respect to the piezoelectric material without damaging other layers of the package substrate (e.g., organic substrate) including organic layers.

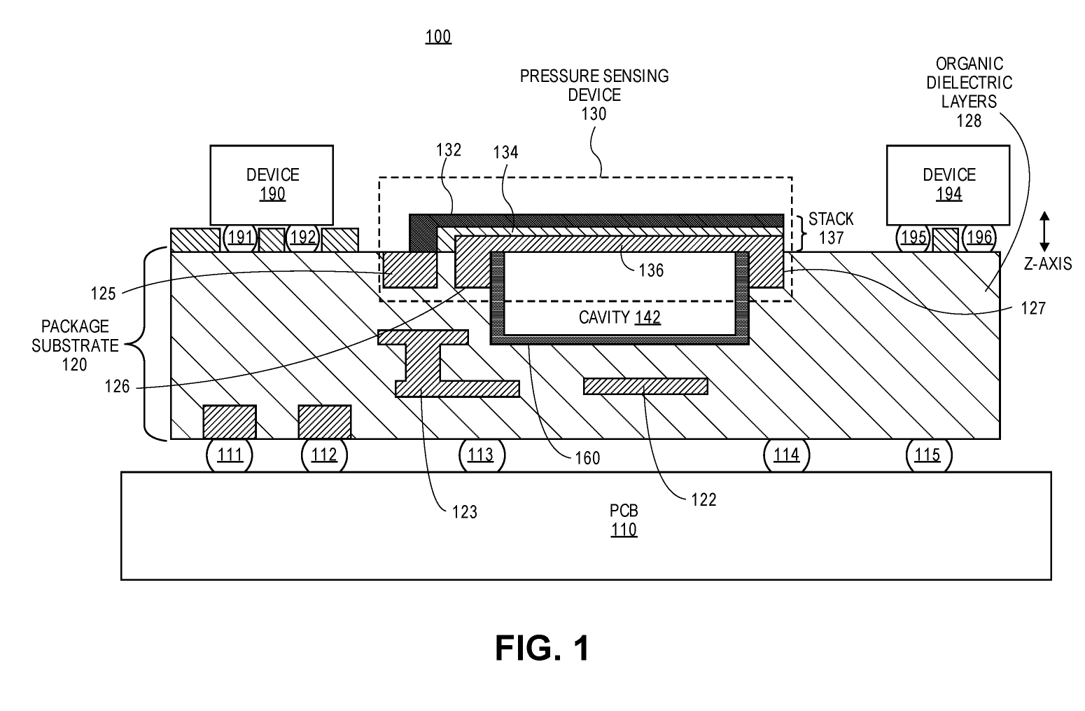

Referring now to FIG. 1, a view of a microelectronic device 100 having package-integrated piezoelectric devices is shown, according to an embodiment. In one example, the microelectronic device 100 includes multiple devices 190 and 194 (e.g., die, chip, CPU, silicon die or chip, radio transceiver, etc.) that are coupled or attached to a package substrate 120 with solder balls 191-192, 195-196. The package substrate 120 is coupled or attached to the printed circuit board (PCB) 110 using, for example, solder balls 111 through 115.

The package substrate 120 (e.g., organic substrate) includes organic dielectric layers 128 and conductive layers 122-123, 125-127, 132, and 136. Organic materials may include any type of organic material such as flame retardant 4 (FR4), resin-filled polymers, prepreg (e.g., pre impregnated, fiber weave impregnated with a resin bonding agent), polymers, silica-filled polymers, etc. The package substrate 120 can be formed during package substrate processing (e.g., at panel level). The panels formed can be large (e.g., having in-plane (x, y) dimensions of approximately 0.5 meter by 0.5 meter, or greater than 0.5 meter, etc.) for lower cost. A cavity 142 is formed within the packaging substrate 120 by removing one or more layers (e.g., organic layers, dielectric layers, etc.) from the packaging substrate 120. The cavity 142 can be sealed with a hermetically sealing material 160. In one example, a piezoelectric pressure sensing device 130 (e.g., pressure sensor) is formed with conductive structures 132 and 136 (e.g., beams, traces) and piezoelectric material 134. The three structures 132, 134, and 136 form a stack 137. The conductive structure 132 can act as a first electrode and the conductive movable base structure 136 can act as a second electrode of the piezoelectric vibrating device. The cavity 142 can be air filled or vacuum filled.

The base structure 136 (e.g., deflecting membrane 136) is free to vibrate in a vertical direction (e.g., along a z-axis). It is anchored on the cavity edges by package vias 126 and 127 which serve as both mechanical anchors as well as electrical connections to the rest of the package. The cavity 142 is made airtight by ensuring that its inner surfaces are all patterned or coated with a hermetically sealing material 160 (e.g., metal, SiN, SiO2, etc). This ensures that the pressure inside the cavity remains isolated from the pressure outside. Changes in the outside (ambient) pressure in comparison to a reference pressure value produce a pressure differential that causes the membrane 136 to deflect in the vertical direction (e.g., z-axis).

To measure the deflection (and thus the change in pressure), a piezoelectric stack 137 is deposited on the membrane. When the membrane 136 with the piezoelectric film deflects due to pressure changes, a voltage proportional to the membrane deflection is generated in the piezoelectric material. This voltage is measured electrically between the electrodes of the stack 137 to determine the corresponding pressure change.

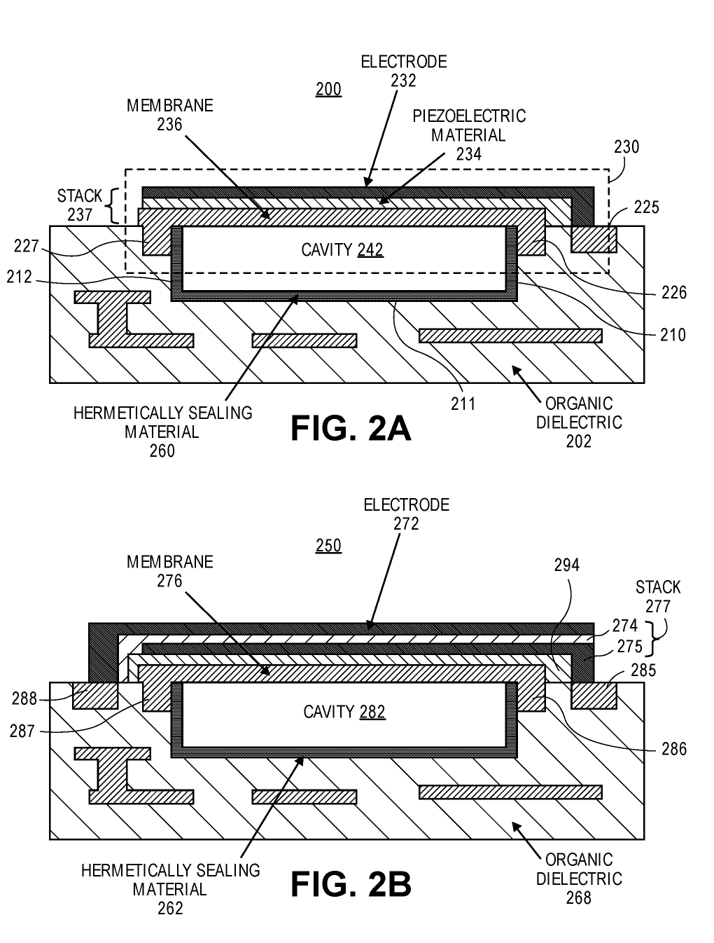

FIG. 2A illustrates a side cross-sectional view of a package substrate having a package-integrated piezoelectric pressure sensing device, according to an embodiment. In one example, the package substrate 200 may be coupled or attached to multiple devices (e.g., die, chip, CPU, silicon die or chip, RF transceiver, etc.) and may be also coupled or attached to a printed circuit board (e.g., PCB 110). The package substrate 200 (e.g., organic substrate) includes organic dielectric layers 202 and conductive layers 225-227, 232, and 236. The package substrate 200 can be formed during package substrate processing (e.g., at panel level). A cavity 242 is formed within the packaging substrate 200 by removing one or more layers (e.g., organic layers, dielectric layers, etc.) from the packaging substrate 200. In one example, a piezoelectric pressure sensing device is formed with conductive structures 232 and 236 and piezoelectric material sandwiched between them. The conductive structure 232 can act as a top electrode and the conductive movable base structure 236 (e.g., membrane 236) can act as a bottom electrode of the piezoelectric device. The cavity 242 can be air filled or vacuum filled. The conductive structure 236 is anchored on edges by package connections 226 and 227 (e.g., anchors, vias) which may serve as both mechanical anchors as well as electrical connections to the rest of the package.

The base structure 236 (e.g., membrane 236) can be patterned as part of one of the substrate conductive layers (e.g., copper traces). A cavity 242 is formed within the packaging substrate 200 by removing one or more layers (e.g., organic layers, dielectric layers, etc.) from the packaging substrate 200 to allow the membrane to move and to create a reference pressure chamber. The cavity 242 is made airtight by ensuring that its inner surfaces 210-212 are all patterned or coated with a hermetically sealing material 260 (e.g., metal, SiN, SiO2, etc). This ensures that the pressure inside the cavity remains isolated from the pressure outside. Changes in the outside (ambient) pressure produce a pressure differential that causes the membrane to deflect in the vertical direction.

To measure the deflection and thus the change in pressure, a piezoelectric stack 237 is deposited on the membrane. The stack 237 includes a piezoelectric material 234 (e.g., PZT, KNN, ZnO, or other materials) sandwiched between conductive electrodes. The membrane itself can be used as one of the electrodes as shown in FIG. 2A, or alternatively, a separate conductive material 275 can be used for this bottom electrode as illustrated in FIG. 2B which illustrates a side cross-sectional view of a package substrate 250 having a package-integrated piezoelectric pressure sensing device, according to an embodiment. If the membrane 276 is conducting, then an insulating layer 294 can be deposited on the membrane 276 first to electrically decouple the bottom electrode 275 from the conductive membrane 276. The package substrate 250 includes organic dielectric layers 268 and conductive layers 285-288, 272, 275, and 276. A cavity 282 is formed within the packaging substrate 250 by removing one or more layers (e.g., organic layers, dielectric layers, etc.) from the packaging substrate 250. In one example, a piezoelectric pressure sensing device is formed with a stack 277 that includes conductive vibrating structures 272 and 275 and piezoelectric material 274 sandwiched between them.

When a membrane (e.g., 236, 276) having a minimal thickness is physically or mechanically coupled with the piezoelectric material (e.g., 234, 274), this membrane deflects due to pressure changes and a voltage proportional to the membrane deflection is generated in the piezoelectric material. This voltage is measured electrically between the electrodes to determine the corresponding pressure change. In one example, an ambient pressure that is greater than the cavity pressure causes a downward deflection of the membrane.

The cavity (e.g., 242, 282) needs to be airtight to keep the pressure inside it isolated from the outside pressure. Due to the porous nature of organic dielectric layers, the inner walls of the cavity need to be coated or patterned with a hermetically sealing material (e.g., 260, 262) such as metal or ceramic or other sealing materials. This can be accomplished, e.g., by using Copper (Cu) layers for the top and bottom walls and a Cu ring of vias for the side walls, or by depositing a hermetic layer (e.g., SiN, SiO2, etc) having a certain thickness (e.g., 50-100 nanometers, etc.) to coat the inner walls after the cavity is created.

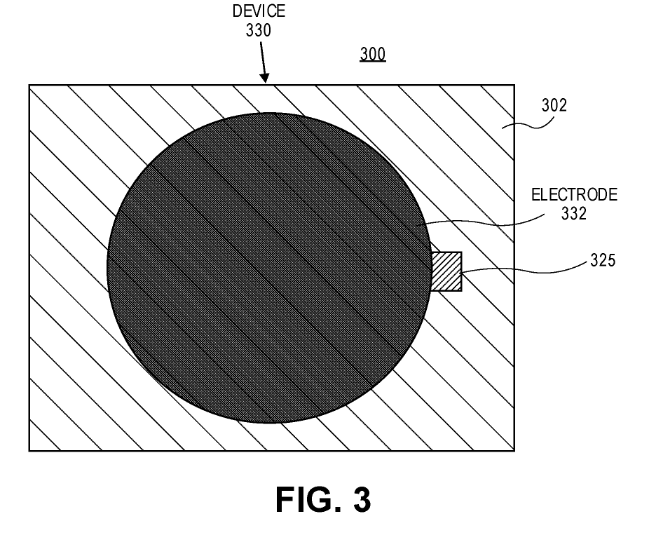

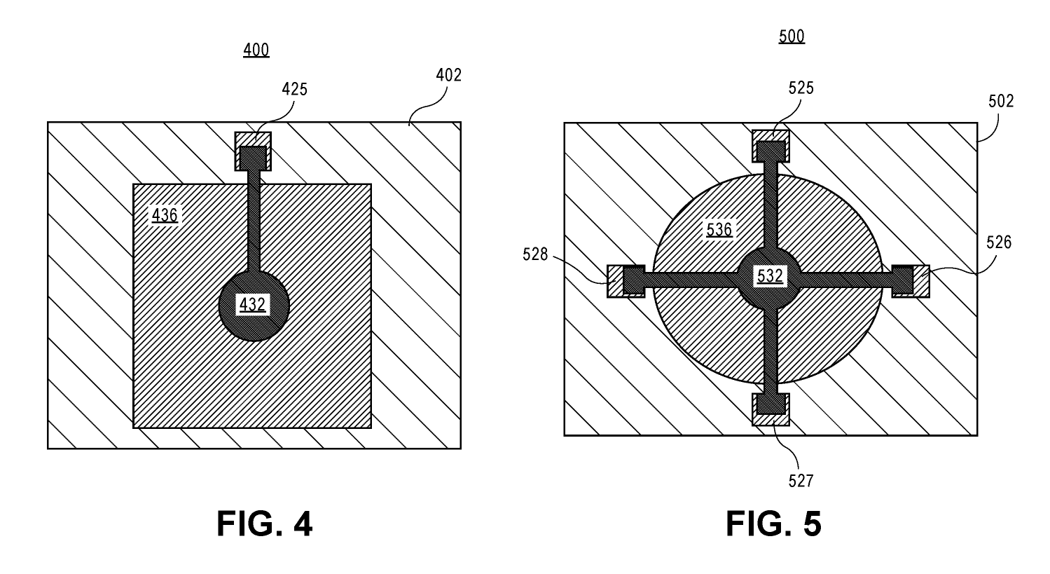

FIG. 3 illustrates a top view of a package substrate having a package-integrated piezoelectric device 330 (e.g., pressure sensing device), according to another embodiment. The package substrate 300 (e.g., organic substrate), which includes organic dielectric layers 302 and conductive layers 332 and 325, can be formed during package substrate processing (e.g., at panel level). The package substrate 300 may be a top view of the pressure sensing device 230 of FIG. 2A.

A cavity is formed within the package substrate 300 by removing one or more organic dielectric layers 302 from the substrate 300. In one example, a piezoelectric pressure sensing device is formed with conductive vibrating structures and piezoelectric material sandwiched between them. The conductive structure 332 can act as a top electrode and either a region of the conductive movable base structure (e.g., membrane 236 of FIG. 2A) or a separate structure can act as a bottom electrode of the piezoelectric device.

Although FIG. 3 shows one specific membrane shape (e.g., circular), other embodiments can have other membrane shapes (e.g., FIGS. 4-8, square, rectangle, other polygon shape, etc.) in order to achieve different voltage response characteristics. A membrane having a larger area would generate a larger voltage between the electrodes. Also, different electrode shapes can be envisioned with contacts on one or more sides of the cavity. Similarly, a piezoelectric stack does not need to cover an entire membrane as shown in FIGS. 4-8.

FIG. 4 illustrates a top view of a package substrate having a package-integrated piezoelectric device (e.g., pressure sensing device with square shaped membrane), according to another embodiment. The package substrate 400 (e.g., organic substrate), which includes organic dielectric layers 402 and conductive layers 425, 432, and 436, can be formed during package substrate processing (e.g., at panel level).

In one example, the package substrate 400 may be coupled or attached to multiple devices (e.g., die, chip, CPU, silicon die or chip, RF transceiver, etc.) and may be also coupled or attached to a printed circuit board (e.g., PCB 110). A cavity is formed within the package substrate 400 by removing one or more organic dielectric layers 402 from the substrate 400. In one example, a piezoelectric pressure sensing device is formed with conductive structures 432 and 436 and piezoelectric material sandwiched between them. The conductive structure 432 can act as a top electrode and either a region of the conductive movable base structure 436 (e.g., deflecting membrane 436) or a separate structure can act as a bottom electrode of the piezoelectric device. In one example, the piezoelectric material is disposed on the bottom electrode and the top electrode is disposed on the piezoelectric material. The cavity can be air filled or vacuum filled. The conductive structure 432 is anchored on one edge by package connection 425 (e.g., anchors, vias) which may serve as both a mechanical anchor as well as an electrical connection to the rest of the package.

FIG. 5 illustrates a top view of a package substrate having a package-integrated piezoelectric device (e.g., pressure sensing device with circular shaped membrane), according to another embodiment. The package substrate 500 (e.g., organic substrate), which includes organic dielectric layers 502 and conductive layers 525-528, 532, and 536, can be formed during package substrate processing (e.g., at panel level).

In one example, the package substrate 500 may be coupled or attached to multiple devices (e.g., die, chip, CPU, silicon die or chip, RF transceiver, etc.) and may be also coupled or attached to a printed circuit board (e.g., PCB 110). A cavity is formed within the package substrate 500 by removing one or more organic dielectric layers 502 from the substrate 500. In one example, a piezoelectric pressure sensing device is formed with conductive structures 532 and 536 and piezoelectric material sandwiched between them. The conductive structure 532 can act as a top electrode and either a region of the conductive movable base structure 536 (e.g., deflecting membrane 536) or a separate structure can act as a bottom electrode of the piezoelectric device. In one example, the piezoelectric material is disposed on the bottom electrode and the top electrode is disposed on the piezoelectric material. The cavity can be air filled or vacuum filled. The conductive structure 532 is anchored by package connections 525-528 (e.g., anchors, vias) which may serve as both mechanical anchors as well as an electrical connections to the rest of the package.

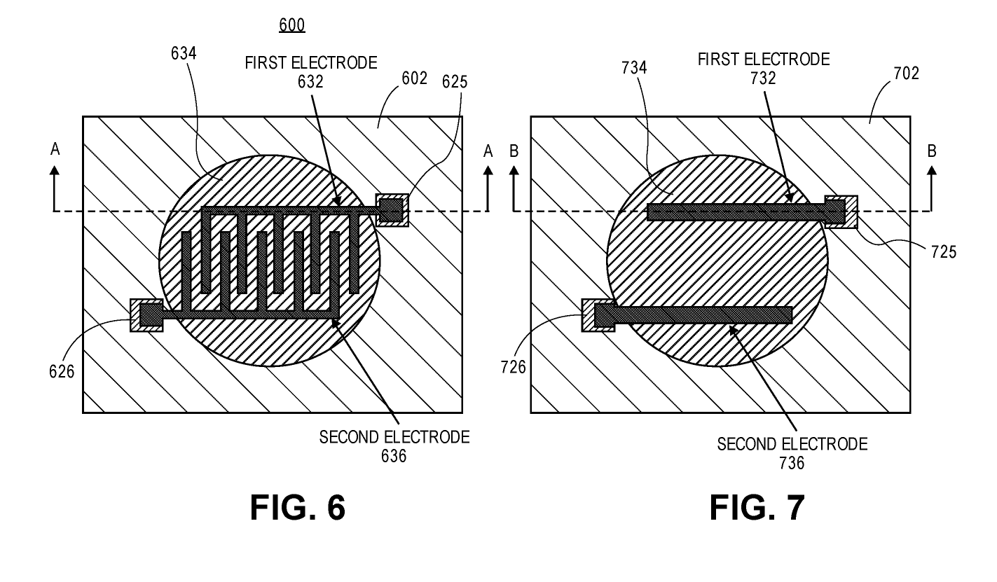

FIG. 6 illustrates a top view of a package substrate having a package-integrated piezoelectric device (e.g., pressure sensing device with interdigitated electrodes), according to another embodiment. The package substrate 600 (e.g., organic substrate), which includes organic dielectric layers 602 and conductive layers 625-626, 632, and 636, can be formed during package substrate processing (e.g., at panel level).

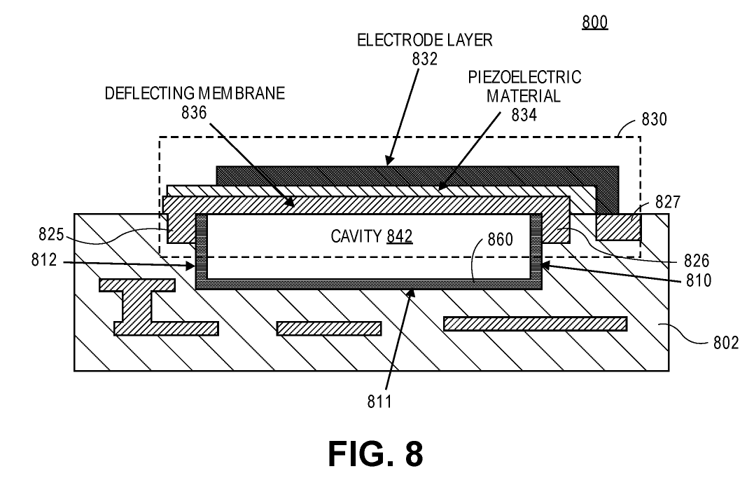

In one example, the package substrate 600 may be coupled or attached to multiple devices (e.g., die, chip, CPU, silicon die or chip, RF transceiver, etc.) and may be also coupled or attached to a printed circuit board (e.g., PCB 110). A cavity is formed within the package substrate 600 by removing one or more organic dielectric layers 602 from the substrate 600. In one example, a piezoelectric pressure sensing device is formed with conductive structures 632 and 636 and piezoelectric material 634. The conductive structures 632 and 636 function as first and second interdigitated electrodes on a same side of the piezoelectric material 634. A deflecting membrane (e.g., 836 in FIG. 8 which represents a cross-sectional view AA of FIG. 6) deflects in response to a change in ambient pressure. A cavity (e.g., 842 in FIG. 8) can be air filled or vacuum filled. The electrodes 632 and 636 are anchored by package connections 625-626 (e.g., anchors, vias) which may serve as both mechanical anchors as well as electrical connections to the rest of the package.

FIG. 7 illustrates a top view of a package substrate having a package-integrated piezoelectric device (e.g., pressure sensing device with first and second electrodes disposed on piezoelectric material), according to another embodiment. The package substrate 700 (e.g., organic substrate), which includes organic dielectric layers 702 and conductive layers 725-726, 732, and 736, can be formed during package substrate processing (e.g., at panel level).

In one example, the package substrate 700 may be coupled or attached to multiple devices (e.g., die, chip, CPU, silicon die or chip, RF transceiver, etc.) and may be also coupled or attached to a printed circuit board (e.g., PCB 110). A cavity is formed within the package substrate 700 by removing one or more organic dielectric layers 702 from the substrate 700. In one example, a piezoelectric pressure sensing device is formed with conductive structures 732 and 736 and piezoelectric material 734. The conductive structures 732 and 736 function as first and second electrodes on a same side of the piezoelectric material 734 while a deflecting membrane (e.g., 836 in FIG. 8 which represents a cross-sectional view BB of FIG. 7) deflects in response to a change in ambient pressure. A cavity (e.g., 842 in FIG. 8) can be air filled or vacuum filled. The electrodes 732 and 736 are anchored by package connections 725-726 (e.g., anchors, vias) which may serve as both mechanical anchors as well as electrical connections to the rest of the package.

FIG. 8 illustrates a cross-sectional view AA of FIG. 6 and also a cross-sectional view BB of FIG. 7 of a package substrate having a package-integrated piezoelectric device (e.g., pressure sensing device with first and second electrodes disposed on a same side of a piezoelectric material), according to another embodiment. The package substrate 800 (e.g., organic substrate), which includes organic dielectric layers 802 and conductive layers 825-827, 832, and 836, can be formed during package substrate processing (e.g., at panel level).

In one example, the package substrate 800 may be coupled or attached to multiple devices (e.g., die, chip, CPU, silicon die or chip, RF transceiver, etc.) and may be also coupled or attached to a printed circuit board (e.g., PCB 110). A cavity 842 is formed within the package substrate 800 by removing one or more organic dielectric layers 802 from the substrate 800. In one example, a piezoelectric pressure sensing device 830 is formed with conductive structures 832 and 636 or 736, deflecting membrane 836, and piezoelectric material 834. The conductive structures 832 and 636 or 736 function or act as first and second electrodes on a same side of the piezoelectric material 834 while a deflecting membrane 836 deflects in response to a change in ambient pressure. A cavity 842 can be air filled or vacuum filled. The cavity 842 is made airtight by ensuring that its inner surfaces 810-812 are all patterned or coated with a hermetically sealing material 860 (e.g., metal, SiN, SiO2, etc). The electrodes and membrane are anchored by package connections 825-827 (e.g., anchors, vias) which may serve as both mechanical anchors as well as electrical connections to the rest of the package.

It will be appreciated that, in a system on a chip embodiment, the die may include a processor, memory, communications circuitry and the like. Though a single die is illustrated, there may be none, one or several dies included in the same region of the microelectronic device.

In one embodiment, the microelectronic device may be a crystalline substrate formed using a bulk silicon or a silicon-on-insulator substructure. In other implementations, the microelectronic device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of the present invention.

The microelectronic device may be one of a plurality of microelectronic devices formed on a larger substrate, such as, for example, a wafer. In an embodiment, the microelectronic device may be a wafer level chip scale package (WLCSP). In certain embodiments, the microelectronic device may be singulated from the wafer subsequent to packaging operations, such as, for example, the formation of one or more piezoelectric vibrating devices.

One or more contacts may be formed on a surface of the microelectronic device. The contacts may include one or more conductive layers. By way of example, the contacts may include barrier layers, organic surface protection (OSP) layers, metallic layers, or any combination thereof. The contacts may provide electrical connections to active device circuitry (not shown) within the die. Embodiments of the invention include one or more solder bumps or solder joints that are each electrically coupled to a contact. The solder bumps or solder joints may be electrically coupled to the contacts by one or more redistribution layers and conductive vias.

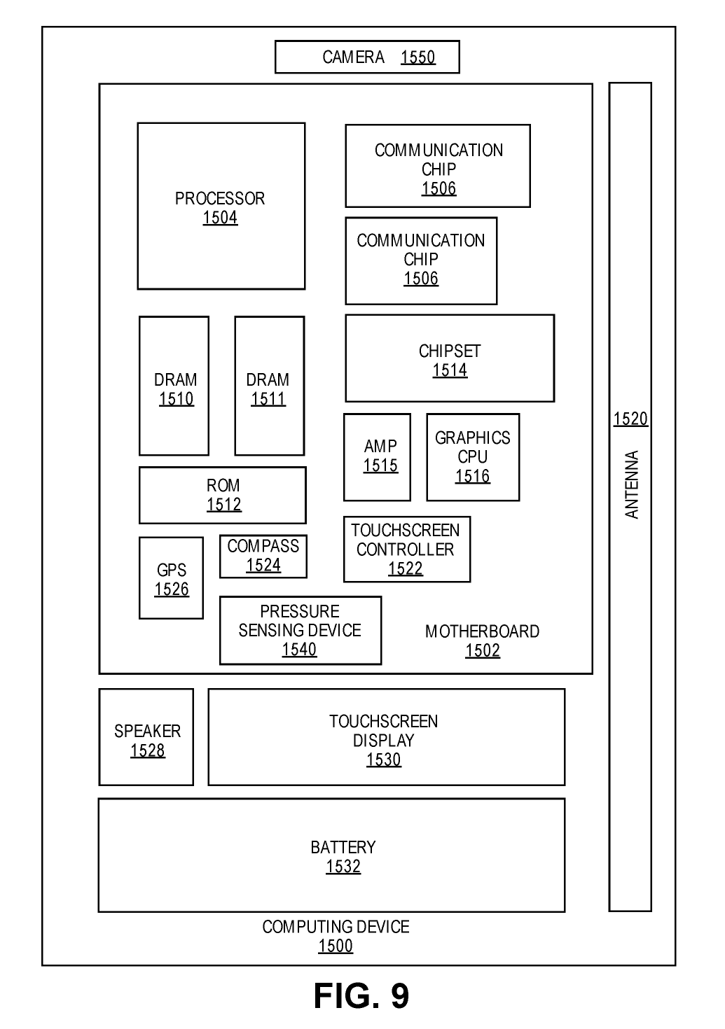

FIG. 9 illustrates a computing device 1500 in accordance with one embodiment of the invention. The computing device 1500 houses a board 1502. The board 1502 may include a number of components, including but not limited to a processor 1504 and at least one communication chip 1506. The processor 1504 is physically and electrically coupled to the board 1502. In some implementations the at least one communication chip 1506 is also physically and electrically coupled to the board 1502. In further implementations, the communication chip 1506 is part of the processor 1504.

Depending on its applications, computing device 1500 may include other components that may or may not be physically and electrically coupled to the board 1502. These other components include, but are not limited to, volatile memory (e.g., DRAM 1510, 1511), non-volatile memory (e.g., ROM 1512), flash memory, a graphics processor 1516, a digital signal processor, a crypto processor, a chipset 1514, an antenna 1520, a display, a touchscreen display 1530, a touchscreen controller 1522, a battery 1532, an audio codec, a video codec, a power amplifier 1515, a global positioning system (GPS) device 1526, a compass 1524, a pressure sensing device 1540 (e.g., a piezoelectric pressure sensing device), a gyroscope, a speaker, a camera 1550, and a mass storage device (such as hard disk drive, compact disk (CD), digital versatile disk (DVD), and so forth).

The communication chip 1506 enables wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1500 may include a plurality of communication chips 1506. For instance, a first communication chip 1506 may be dedicated to shorter range wireless communications such as Wi-Fi, WiGig and Bluetooth and a second communication chip 1506 may be dedicated to longer range wireless communications such as GPS, EDGE, GPRS, CDMA, WiMAX, LTE, Ev-DO, 5G, and others.

The processor 1504 of the computing device 1500 includes an integrated circuit die packaged within the processor 1504. In some implementations of the invention, the integrated circuit processor package or motherboard 1502 includes one or more devices, such as pressure sensing devices in accordance with implementations of embodiments of the invention. The term “processor” may refer to any device or portion of a device that processes electronic data from registers and/or memory to transform that electronic data into other electronic data that may be stored in registers and/or memory. The communication chip 1506 also includes an integrated circuit die packaged within the communication chip 1506. The following examples pertain to further embodiments.

Example 1 is a pressure sensing device comprising a membrane that is positioned in proximity to a cavity of an organic substrate, a piezoelectric material positioned in proximity to the membrane, and an electrode in contact with the piezoelectric material. The membrane deflects in response to a change in ambient pressure and this deflection causes a voltage to be generated in the piezoelectric material with this voltage being proportional to the change in ambient pressure. In example 2, the subject matter of example 1 can optionally include the pressure sensing device being integrated with the organic substrate which is fabricated using panel level processing. The membrane is positioned above the cavity of the organic substrate to allow deflection of the membrane.

In example 3, the subject matter of any of examples 1-2 can optionally include the membrane comprising any type of geometrical shape including a square, a rectangle, a circle, or other polygon shape.

In example 4, the subject matter of any of examples 1-3 can optionally include this voltage being measured between the electrode and the membrane acting as another electrode.

In example 5, the subject matter of any of examples 1-4 can optionally include a hermetically sealing material being disposed on inner surfaces of the cavity to create a sealed reference pressure within the cavity.

In example 6, the subject matter of any of examples 1-5 can optionally include an insulating layer that is disposed on the membrane and an additional electrode that is disposed on the insulating layer which electrically decouples the membrane and the additional electrode.

In example 7, the subject matter of any of examples 1-6 can optionally include the voltage being measured between the electrode and the additional electrode in response to deflection of the membrane.

In example 8, the subject matter of any of examples 1-7 can optionally include the electrode being coupled to a first electrical connection of the organic substrate in proximity to an end of the cavity of the organic substrate and the membrane being coupled to a second electrical connection of the organic substrate in proximity to the same end of the cavity.

Example 9 is a package substrate comprising a plurality of organic dielectric layers and a plurality of conductive layers to form the package substrate, a cavity formed in the package substrate, and a piezoelectric pressure sensing device integrated within the package substrate, which includes a membrane that is positioned in proximity to the cavity, a piezoelectric material positioned in proximity to the membrane, and first and second electrodes in contact with the piezoelectric material. The membrane deflects in response to a change in ambient pressure and this deflection causes a voltage to be generated in the piezoelectric material with this voltage being proportional to the change in ambient pressure.

In example 10, the subject matter of example 9 can optionally include the package substrate being fabricated using panel level processing. The membrane is positioned above the cavity of the package substrate to allow deflection of the membrane.

In example 11, the subject matter of any of examples 9-10 can optionally include the membrane comprising any type of geometrical shape including a square, a rectangle, a circle, or other polygon shape.

In example 12, the subject matter of any of examples 9-11 can optionally include the voltage being measured between the first and second electrodes.

In example 13, the subject matter of any of examples 9-12 can optionally include a hermetically sealing material being disposed on inner surfaces of the cavity to create a sealed reference pressure within the cavity.

Example 14 is a computing device comprising at least one processor to process data and a package substrate coupled to at least one processor. The package substrate includes a plurality of organic dielectric layers and a plurality of conductive layers to form the package substrate which includes a piezoelectric pressure sensing device having a membrane that is positioned in proximity to a cavity of the package substrate, a piezoelectric material positioned in proximity to the membrane, and an electrode in contact with the piezoelectric material. The membrane deflects in response to a change in ambient pressure and this deflection causes a voltage to be generated in the piezoelectric material with this voltage being proportional to the change in ambient pressure.

In example 15, the subject matter of example 14 can optionally include the pressure sensing device being integrated with the package substrate which is fabricated using panel level processing.

In example 16, the subject matter of any of examples 14-15 can optionally include the membrane being positioned above the cavity of the package substrate to allow deflection of the membrane.

In example 17, the subject matter of any of examples 14-16 can optionally include the voltage being measured between the electrode and the membrane acting as another electrode.

In example 18, the subject matter of any of examples 14-17 can optionally include a hermetically sealing material being disposed on inner surfaces of the cavity to create a fixed reference pressure within the cavity.

In example 19, the subject matter of any of examples 14-18 can optionally include an insulating layer being disposed on the membrane and an additional electrode being disposed on the insulating layer which electrically decouples the membrane and the additional electrode.

In example 20, the subject matter of any of examples 14-19 can optionally include the voltage being measured between the electrode and the additional electrode in response to deflection of the membrane.

In example 21, the subject matter of any of examples 14-20 can optionally include a printed circuit board coupled to the package substrate.

1. A pressure sensing device, comprising:
a membrane that is positioned in proximity to a cavity of an organic substrate;
a piezoelectric material positioned in proximity to the membrane; and
an electrode in contact with the piezoelectric material, wherein the membrane to deflect in response to a change in ambient pressure and this deflection causes a voltage to be generated in the piezoelectric material with this voltage being proportional to the change in ambient pressure.

2. The pressure sensing device of claim 1, wherein the pressure sensing device is integrated with the organic substrate which is fabricated using panel level processing, wherein the membrane is positioned above the cavity of the organic substrate to allow deflection of the membrane.

3. The pressure sensing device of claim 2, wherein the membrane comprises any type of geometrical shape including a square, a rectangle, a circle, or other polygon shape.

4. The pressure sensing device of claim 1, wherein this voltage is measured between the electrode and the membrane acting as another electrode.

5. The pressure sensing device of claim 1, further comprising:
a hermetically sealing material disposed on inner surfaces of the cavity to create a sealed reference pressure within the cavity.

6. The pressure sensing device of claim 1, further comprising:
an insulating layer disposed on the membrane; and
an additional electrode disposed on the insulating layer which electrically decouples the membrane and the additional electrode.

7. The pressure sensing device of claim 6, wherein this voltage is measured between the electrode and the additional electrode in response to deflection of the membrane.

8. The pressure sensing device of claim 1, wherein the electrode is coupled to a first electrical connection of the organic substrate in proximity to an end of the cavity of the organic substrate and the membrane is coupled to a second electrical connection of the organic substrate in proximity to the same end of the cavity.

9. A package substrate comprising:
a plurality of organic dielectric layers and a plurality of conductive layers to form the package substrate;
a cavity formed in the package substrate; and
a piezoelectric pressure sensing device integrated within the package substrate, which includes a membrane that is positioned in proximity to the cavity, a piezoelectric material positioned in proximity to the membrane, and first and second electrodes in contact with the piezoelectric material, wherein the membrane to deflect in response to a change in ambient pressure and this deflection causes a voltage to be generated in the piezoelectric material with this voltage being proportional to the change in ambient pressure.

10. The package substrate of claim 9, wherein the package substrate is fabricated using panel level processing, wherein the membrane is positioned above the cavity of the package substrate to allow deflection of the membrane.

11. The package substrate of claim 9, wherein the membrane comprises any type of geometrical shape including a square, a rectangle, a circle, or other polygon shape.

12. The package substrate of claim 9, wherein this voltage is measured between the first and second electrodes.

13. The package substrate of claim 9, further comprising:
a hermetically sealing material disposed on inner surfaces of the cavity to create a sealed reference pressure within the cavity.

14. A computing device comprising:
at least one processor to process data; and
a package substrate coupled to at least one processor, and the package substrate includes a plurality of organic dielectric layers and a plurality of conductive layers to form the package substrate which includes a piezoelectric pressure sensing device having a membrane that is positioned in proximity to a cavity of the package substrate, a piezoelectric material positioned in proximity to the membrane, and an electrode in contact with the piezoelectric material, wherein the membrane deflects in response to a change in ambient pressure and this deflection causes a voltage to be generated in the piezoelectric material with this voltage being proportional to the change in ambient pressure.

15. The computing device of claim 14, wherein the pressure sensing device is integrated with the package substrate which is fabricated using panel level processing.

16. The computing device of claim 14, wherein the membrane is positioned above the cavity of the package substrate to allow deflection of the membrane.

17. The computing device of claim 14, wherein this voltage is measured between the electrode and the membrane acting as another electrode.

18. The computing device of claim 14, further comprising:
a hermetically sealing material disposed on inner surfaces of the cavity to create a fixed reference pressure within the cavity.

19. The computing device of claim 14, further comprising:
an insulating layer disposed on the membrane; and
an additional electrode disposed on the insulating layer which electrically decouples the membrane and the additional electrode.

20. The computing device of claim 19, wherein this voltage is measured between the electrode and the additional electrode in response to deflection of the membrane.

21. The computing device of claim 14, further comprising:
a printed circuit board coupled to the package substrate.
